(19) United States
(12) Patent Application Publication
(10) Pub. No.: US 2025/0167119 A1
(43) Pub. Date: May 22, 2025

(54) SEMICONDUCTOR STRUCTURE

(71) Applicant: TAIWAN SEMICONDUCTOR MANUFACTURING COMPANY LTD., HSINCHU (TW)

(72) Inventors: WEI-CHENG TZENG, TAIPEI (TW); CHING-YU HUANG, HSINCHU CITY (TW); WEI-CHENG LIN, TAICHUNG CITY (TW); JIANN-TYNG TZENG, HSINCHU (TW)

(21) Appl. No.: 18/513,679

(22) Filed: Nov. 20, 2023

(51) Int. Cl. H01L 23/528; H01L 27/088; H01L 29/78

(52) U.S. Cl. CPC H01L 23/5286; H10D 30/63; H10D 84/83

(57) ABSTRACT

The present disclosure provides a semiconductor structure. The semiconductor structure includes: a first layer including a plurality of first power lines; a second layer including a plurality of VFETs; a third layer including a plurality of second power line; wherein the second layer is disposed between the first layer and the third layer, a first part of the VETs is connected to the first power lines and a second part of the VETs is connected to the second power lines.

### BACKGROUND

In conventional semiconductor techniques, planar field effect transistor (FET) is one common type of metal oxide semiconductor field effect transistor (MOSFET). To increase device density and performance, vertical field effect transistor (VFET) is introduced. Regarding VFET which has the top to bottom drain/source structure, the flexibility of routing, power input and pin access need to be increased.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a top view of a part of a semiconductor structure in accordance with some embodiments of the present disclosure.

FIG. 2 is a cross sectional view of the part of the semiconductor structure of FIG. 1 in accordance with some embodiments of the present disclosure.

FIG. 3 is a cross sectional view of the part of the semiconductor structure of FIG. 1 in accordance with some embodiments of the present disclosure.

FIG. 4 is a cross sectional view of the part of the semiconductor structure of FIG. 1 in accordance with some embodiments of the present disclosure.

FIG. 5A is a cross sectional view of an N-type VFET in accordance with some embodiments of the present disclosure.

FIG. 5B is a cross sectional view of an N-type VFET in accordance with some embodiments of the present disclosure.

FIG. 6A is a cross sectional view of a P-type VFET in accordance with some embodiments of the present disclosure.

FIG. 6B is a cross sectional view of a P-type VFET in accordance with some embodiments of the present disclosure.

FIG. 7 is a top view of a part of the semiconductor structure 1 in accordance with some embodiments of the present disclosure.

FIG. 8 is a cross sectional view of the part of the semiconductor structure of FIG. 7 in accordance with some embodiments of the present disclosure.

FIG. 9 is a top view of a part of the semiconductor structure in accordance with some embodiments of the present disclosure.

FIG. 10 is a cross sectional view of the part of the semiconductor structure of FIG. 9 in accordance with some embodiments of the present disclosure.

FIG. 11 is a schematic view of a part of the semiconductor structure in accordance with some embodiments of the present disclosure.

FIG. 12 is a schematic view of a part of the semiconductor structure in accordance with some embodiments of the present disclosure.

FIG. 13 is a schematic view of a part of the semiconductor structure in accordance with some embodiments of the present disclosure.

FIGS. 14A to 14E are schematic views of shapes of bottom pads within a second layer of a part of a semiconductor structure in accordance with some embodiments of the present disclosure.

FIGS. 15A to 15E are schematic views of shapes of top pads within a second layer of a part of a semiconductor structure in accordance with some embodiments of the present disclosure.

FIGS. 16A and 16B are schematic views of shapes of middle pads within a second layer of a part of a semiconductor structure in accordance with some embodiments of the present disclosure.

FIG. 17 is a schematic view of a power tap cell of a part of the semiconductor structure in accordance with some embodiments of the present disclosure.

FIG. 18 is a schematic view of a placement of power tap cells of a part of the semiconductor structure in accordance with some embodiments of the present disclosure.

FIG. 19 is a block diagram of an IC layout diagram generation system in accordance with some embodiments.

FIG. 20 is a block diagram of an IC manufacturing system, and an IC manufacturing flow associated therewith in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In some embodiments, a semiconductor structure of the present disclosure includes a first layer, a second layer and a third layer. The first layer may be a back metal zero layer BM0. The third layer may be a metal zero layer MO. The first layer (i.e., BM0) includes at least two first power lines (e.g., one VDD and one VSS). The third layer (i.e., MO) includes at least two second power lines (e.g., one VDD and one VSS). The second layer includes a plurality of vertical field effect transistors (VFETs). The second layer is disposed between the first layer (i.e., BM0) and the third layer (i.e., MO). Each of the VFETs may optionally connect to one of the first power lines of the first layer (i.e., BM0) or one of the second power lines of the third layer (i.e., MO). In some embodiments, the first power lines of the first layer (i.e., BM0) and the second power lines of the third layer (i.e., MO) extend along the same direction.

In some embodiments, the VFET may be a P-type VFET or an N-type VFET. The P-type VFET includes a drain epitaxy and a source epitaxy. The N-type VFET includes a drain epitaxy and a source epitaxy. One P-type VFET, one N-type VFET and a corresponding gate may be a device.

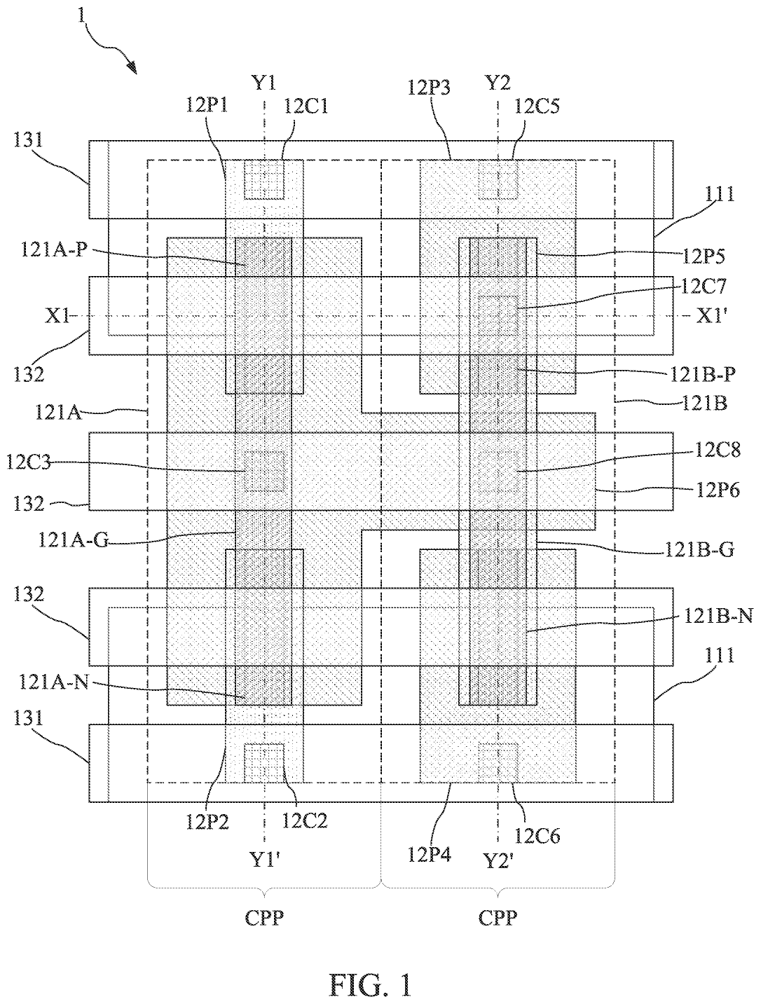

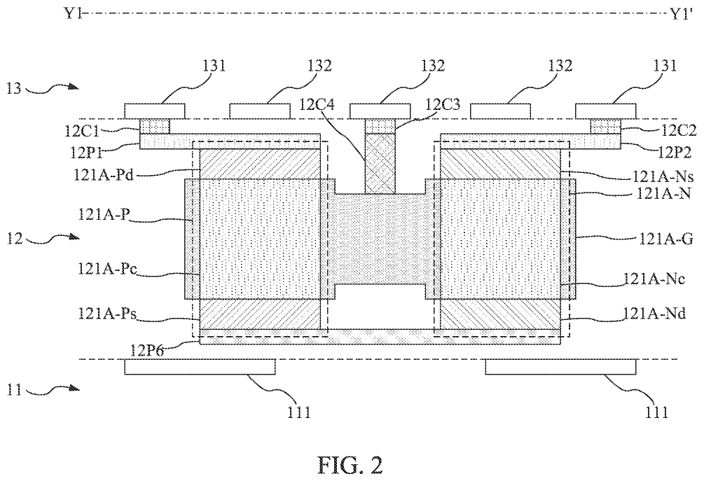

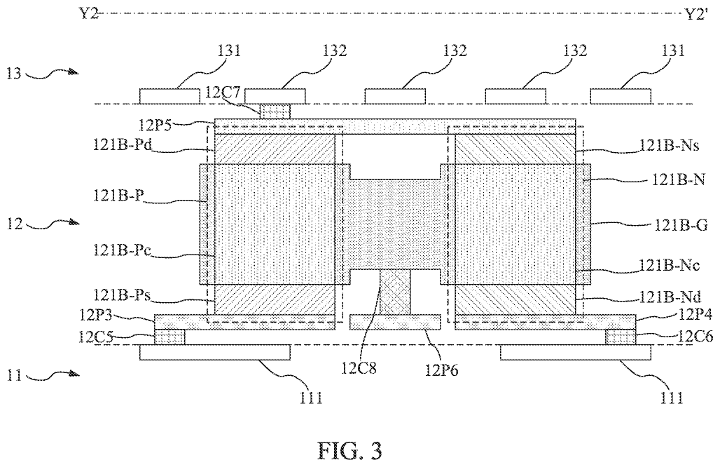

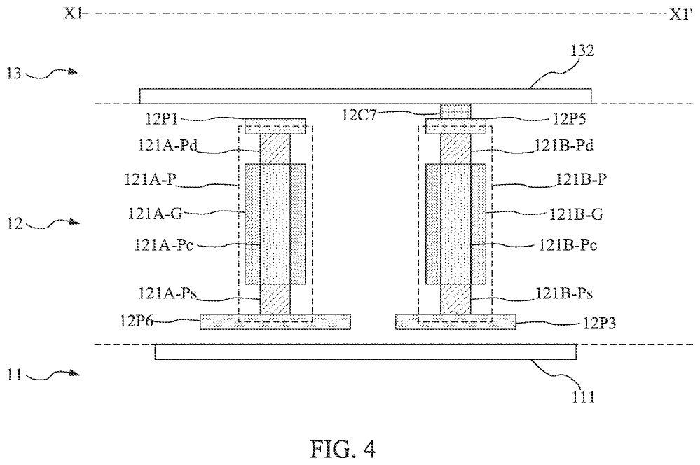

FIG. 1 is a top view of a part of a semiconductor structure 1 in accordance with some embodiments of the present disclosure. FIG. 2 is a cross sectional view of the part of the semiconductor structure 1 along Y1 to Y1′ of FIG. 1 in accordance with some embodiments of the present disclosure. FIG. 3 is a cross sectional view of the part of the semiconductor structure 1 along Y2 to Y2′ of FIG. 1 in accordance with some embodiments of the present disclosure. FIG. 4 is a cross sectional view of the part of the semiconductor structure 1 along X1 to X1′ of FIG. 1 in accordance with some embodiments of the present disclosure.

In some embodiments, the semiconductor structure 1 includes a first layer 11, a second layer 12 and a third layer 13. The second layer 12 is disposed between the first layer 11 and the third layer 13. The first layer 11 includes a plurality of first power lines 111. The third layer 13 includes a plurality of second power lines 131 and a plurality of signal lines 132. In some embodiments, the first power lines 111 and the second power lines provide power to devices within the second layer 12. The signal lines 132 pass signals within the semiconductor structure 1.

In some embodiments, within the second layer 12, there may be a first device 121A. The first device 121A is deployed in a unit which has a contacted poly pitch (CPP). The first device 121A includes an N-type VFET 121A-N, a P-type VFET 121A-P and a gate 121A-G. The P-type VFET 121A-P includes a drain epitaxy 121A-Pd and a source epitaxy 121A-Ps. A channel 121A-Pc is formed between the drain epitaxy 121A-Pd and the source epitaxy 121A-Ps. The N-type VFET 121A-N includes a drain epitaxy 121A-Nd and a source epitaxy 121A-Ns. A channel 121A-Nc is formed between the drain epitaxy 121A-Nd and the source 121A-Ns.

In some embodiments, the drain epitaxy 121A-Pd of the P-type VFET 121A-P connects to one of the second power lines 131 (e.g., the power line used as VDD power line). The source epitaxy 121A-Ns of the N-type VFET 121A-N connects to the other of the second power lines 131 (e.g., the power line used as VSS power line). The gate 121A-G connects to one signal line 132 of the third layer 13.

In some embodiments, the drain epitaxy 121A-Pd of the P-type VFET 121A-P connects to one of the second power lines 131 through a pad 12P1 and a contact 12C1. The contact 12C1 connects to the second power line 131 directly. The pad 12P1 connects the drain epitaxy 121A-Pd of the P-type VFET 121A-P to the contact 12C1. The source epitaxy 121A-Ns of the N-type VFET 121A-N connects to the other of the second power lines 131 through a pad 12P2 and a contact 12C2. The contact 12C2 connects to the second power line 131 directly. The pad 12P2 connects the source epitaxy 121A-Ns of the N-type VFET 121A-N to the contact 12C2. The gate 121A-G connects to the signal line 132 of the third layer 13 through contacts 12C3 and 12C4. The contact 12C3 connects to the signal line 132 directly. The contact 12C4 connects the gate 121A-G to the contact 12C3.

In some embodiments, within the second layer 12, there may be a second device 121B. The second device 121B is deployed in a unit which has a CPP. The second device 121A includes an N-type VFET 121B-N, a P-type VFET 121B-P and a gate 121B-G. The P-type VFET 121B-P includes a drain epitaxy 121B-Pd and a source epitaxy 121B-Ps. A channel 121B-Pc is formed between the drain epitaxy 121B-Pd and the source epitaxy 121B-Ps. The N-type VFET 121B-N includes a drain epitaxy 121B-Nd and a source epitaxy 121B-Ns. A channel 121B-Nc is formed between the drain epitaxy 121B-Nd and the source 121B-Ns.

In some embodiments, the source epitaxy 121B-Ps of the P-type VFET 121B-P connects to one of the first power lines 111 (e.g., the power line used as VDD power line). The drain epitaxy 121B-Nd of the N-type VFET 121B-N connects to the other of the first power lines 111 (e.g., the power line used as VSS power line). The drain epitaxy 121B-Pd of the P-type VFET 121B-P connects to a signal line 132B of the third layer 13.

In some embodiments, the source epitaxy 121B-Ps of the P-type VFET 121B-P connects to one of the first power lines 111 through a pad 12P3 and a contact 12C5. The contact 12C5 connects to the first power line 111 directly. The pad 12P3 connects the source epitaxy 121B-Ps of the P-type VFET 121B-P to the contact 12P5. The drain epitaxy 121B-Nd of the N-type VFET 121B-N connects to the other of the first power lines 111 through a pad 12P4 and a contact 12C6. The contact 12C6 connects to the first power line 111 directly. The pad 12P4 connects the drain epitaxy 121B-Nd of the N-type VFET 121B-N to the contact 12C6. The drain epitaxy 121B-Pd of the P-type VFET 121B-P connects to the signal line 132 through a pad 12P5 and a contact 12C7. The contact 12C7 connects to the signal line 132 directly. The pad 12P5 connects the drain epitaxy 121B-Pd, the source epitaxy 121B-Ns and the contact 12C7.

In some embodiments, a pad 12P6 connects the source epitaxy 121A-Ps of the P-type VFET 121A-P, the drain epitaxy 121A-Nd of the N-type VFET 121A-N and the gate 121B-G. The pad 12P6 may have a ‘T’ shape as shown in FIG. 1 so that the pad 12P6 may connect the source epitaxy 121A-Ps, the drain epitaxy 121A-Nd and the gate 121B-G. In some embodiments, the pad 12P6 connects the source epitaxy 121A-Ps and the drain epitaxy 121A-Nd directly, and connects the gate 121B-G through a contact 12C8.

In some embodiments, when the first device 121A is triggered by a first signal from the signal line 132 to the gate 121A-G, a second signal is delivered from the first device 121A to the second device 121B through the pad 12P6 and the gate 121B-G. Then, the second device 121A is triggered by the second signal and a third signal is delivered from the second device 121B to the signal line 132 connected with the contact 12C7.

In some embodiments, for the VFET(s) of the device(s) within the second layer 12 to optionally connect to the first power lines 111 in the first layer 11 or the second power lines 131 in the third layer 13, the first power lines 111 in the first layer 11 and the second power lines 131 in the third layer 13may extend along the same direction. In some embodiments, the signal lines 132 and the second power lines 131 in the third layer 13 may extend along the same direction. In some embodiments, the power lines 111, 131 and the signal lines 132 are conductive lines made of metal materials or conductive materials.

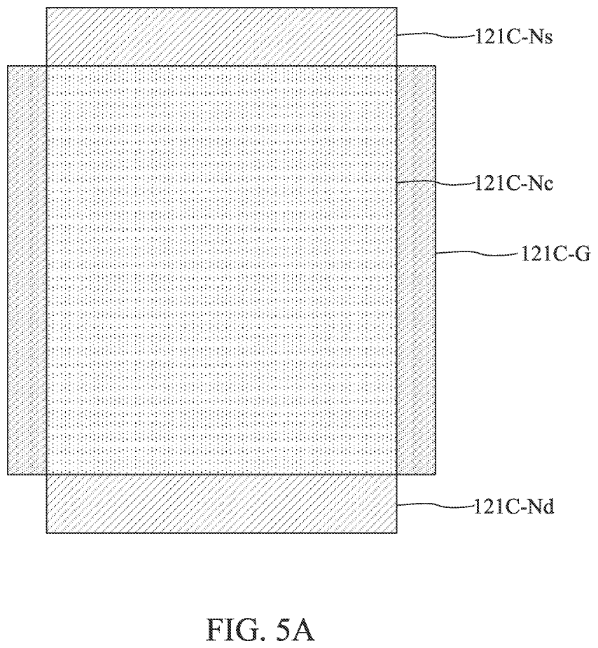

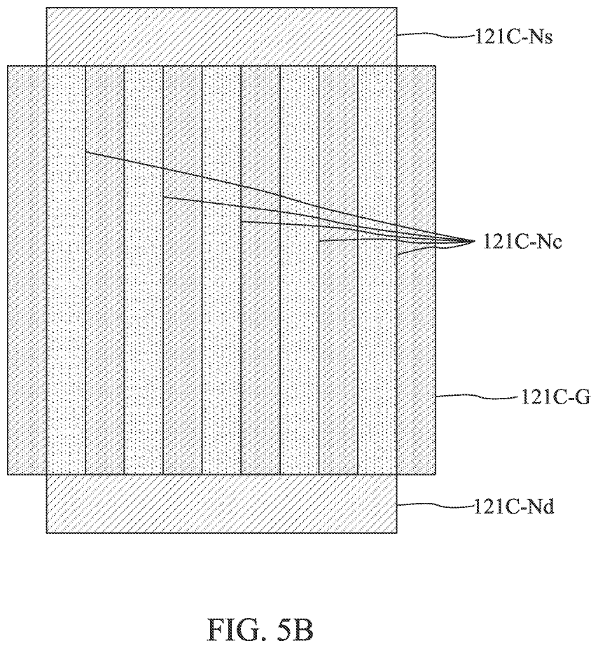

FIG. 5A is a cross sectional view of an N-type VFET 121C-N in accordance with some embodiments of the present disclosure. The N-type VFET 121C-N includes a drain epitaxy 121C-Nd and a source epitaxy 121C-Ns. A channel 121C-Nc is formed between the drain epitaxy 121C-Nd and the source epitaxy 121C-Ns. FIG. 5B is a cross sectional view of another N-type VFET 121D-N in accordance with some embodiments of the present disclosure. The N-type VFET 121D-N includes a drain epitaxy 121D-Nd and a source epitaxy 121D-Ns. A plurality of channels 121D-Nc are formed between the drain epitaxy 121D-Nd and the source epitaxy 121D-Ns.

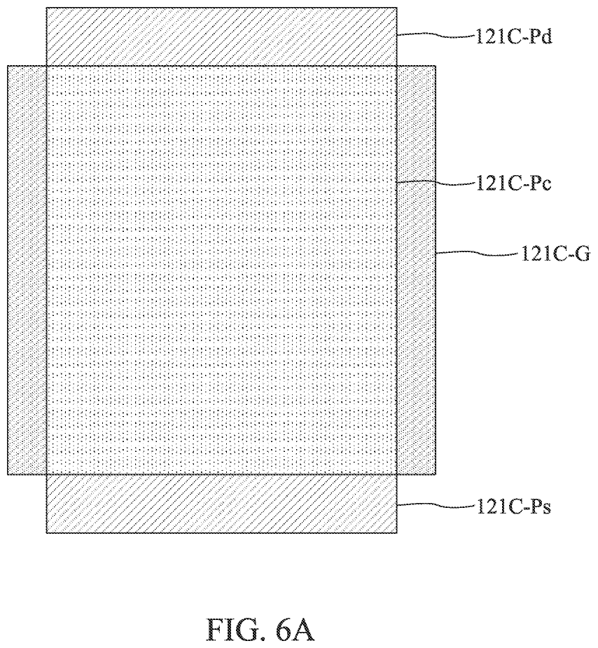

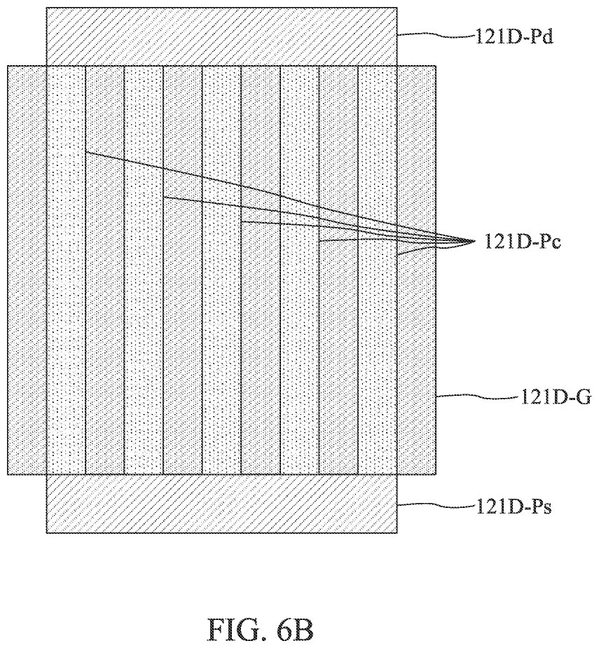

FIG. 6A is a cross sectional view of a P-type VFET 121C-P in accordance with some embodiments of the present disclosure. The P-type VFET 121C-P includes a drain epitaxy 121C-Pd and a source epitaxy 121C-Ps. A channel 121C-Pc is formed between the drain epitaxy 121C-Pd and the source epitaxy 121C-Ps. FIG. 6B is a cross sectional view of another P-type VFET 121D-P in accordance with some embodiments of the present disclosure. The P-type VFET 121D-P includes a drain epitaxy 121D-Pd and a source epitaxy 121D-Ps. A plurality of channels 121D-Pc are formed between the drain epitaxy 121D-Pd and the source epitaxy 121D-Ps.

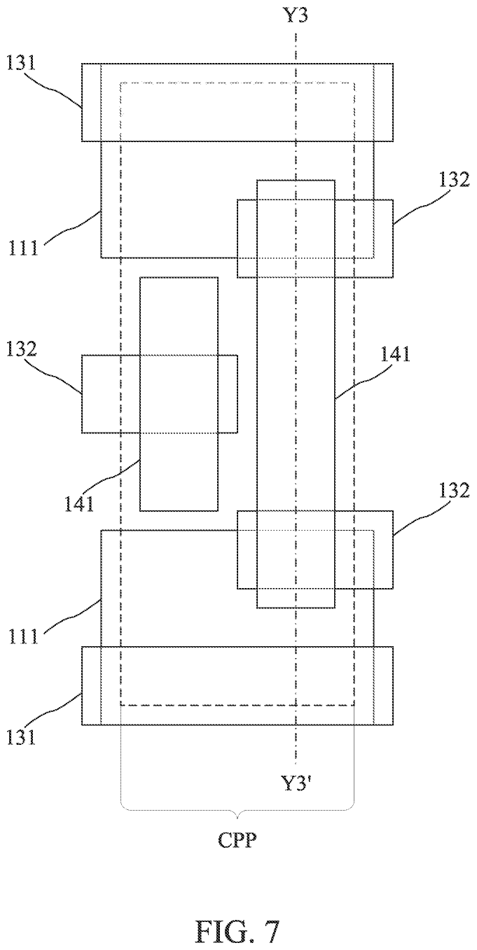

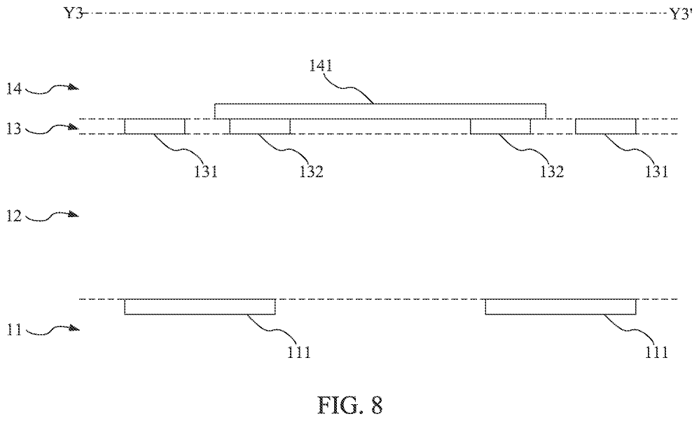

FIG. 7 is a top view of a part of the semiconductor structure 1 in accordance with some embodiments of the present disclosure. FIG. 8 is a cross sectional view of the part of the semiconductor structure 1 along Y3 to Y3′ of FIG. 7 in accordance with some embodiments of the present disclosure. The semiconductor structure 1 includes a fourth layer 14. The fourth layer 14 is disposed above the third layer 13. The fourth layer 14 includes a plurality of second signal lines 141.

In some embodiments, the first signal lines 131 extend along a first direction. The second signal lines 141 extend along a second direction. The first direction is perpendicular to the second direction. In some embodiments, within one CPP, a ratio of the second signal lines 141 to one CPP is greater than 2. In other words, within one CPP, more than 2 second signal lines 141 may be deployed. It should be noted that, in FIGS. 7 and 8, the elements in the second layer 12 are omitted for easy understanding, but it is not intended to limit the implementation of the semiconductor structure 1.

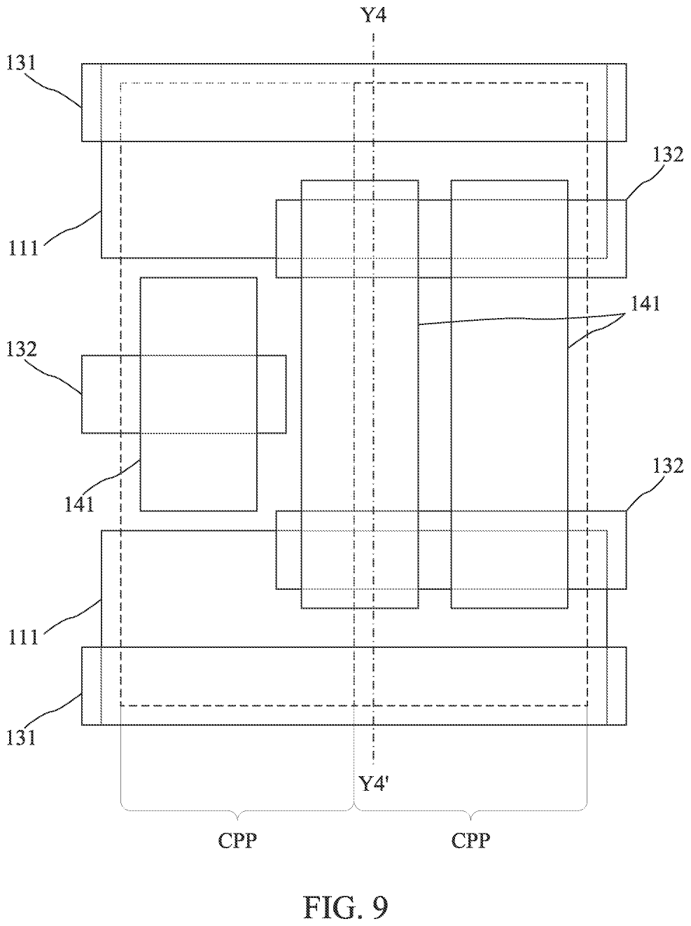

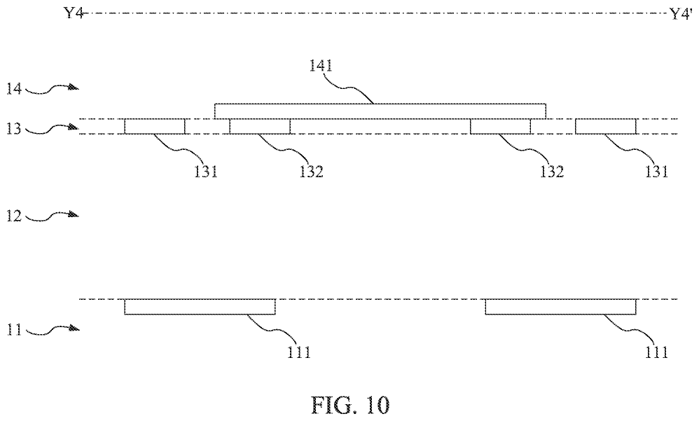

FIG. 9 is a top view of a part of the semiconductor structure 1 in accordance with some embodiments of the present disclosure. FIG. 10 is a cross sectional view of the part of the semiconductor structure 1 along Y4 to Y4′ of FIG. 9 in accordance with some embodiments of the present disclosure. In some embodiments, within one CPP, a ratio of the second signal lines 141 to one CPP is greater than 1.5. In other words, within two CPP, more than 3 second signal lines 141 may be deployed. It should be noted that, in FIGS. 9 and 10, the elements in the second layer 12 are omitted for easy understanding, but it is not intended to limit the implementation of the semiconductor structure 1.

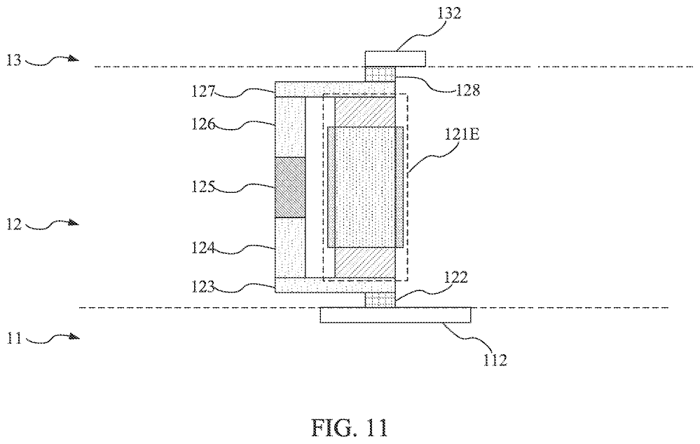

FIG. 11 is a schematic view of a part of the semiconductor structure 1 in accordance with some embodiments of the present disclosure. The second layer 12 includes a first contact 122, a first pad 123, a second contact 124, a second pad 125, a third pad 126, a fourth pad 127 and a second contact 128, which are connected vertically with respect to the layers.

The first contact 122 (e.g., a via) connects a signal line 112 (e.g., a metal line in metal zero layer MO) of the first layer 11 to the first pad 123 (e.g., a bottom pad). The first pad 123 connects the first contact 122 to the second contact 124 (e.g., a deep via). The second contact 124 connects the first pad 123 to the second pad 125 (e.g., a pad in a metal layer-to-poly layer MP). The second pad 125 connects the second contact 124 to the third pad 126 (e.g., a pad in a second metal layer-to-poly layer MP2). The third pad 126 connects the second pad 125 to the fourth pad 127 (e.g., a top pad). The fourth pad 127 connects the third pad 126 to the second contact 128 (e.g., a via). The second contact 128 connects the fourth pad 127 to the second signal line 131 of the third layer 13. The first pad 123 connects to a source/drain terminal of a device 121E of the second layer 12. The fourth pad 127 connects to a source/drain terminal of the device 121E. In these embodiments, the signal may be transmitted from the signal line 112 of the first layer 11 to the second signal line 131 of the second layer 12.

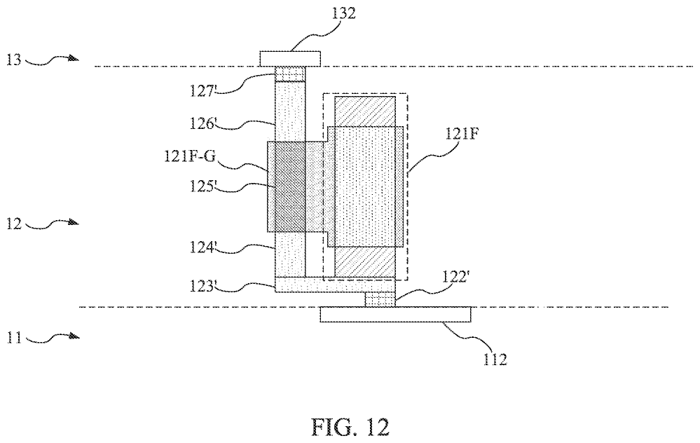

FIG. 12 is a schematic view of a part of the semiconductor structure 1 in accordance with some embodiments of the present disclosure. The second layer 12 includes a first contact 122′, a first pad 123′, a second contact 124′, a second pad 125′, a third pad 126′ and a second contact 127′, which are connected vertically with respect to the layers.

The first contact 122′ (e.g., a via) connects a signal line 112 (e.g., a metal line in metal zero layer MO) of the first layer 11 to the first pad 123′ (e.g., a bottom pad). The first pad 123′ connects the first contact 122′ to the second contact 124′ (e.g., a deep via). The second contact 124′ connects the first pad 123′ to the second pad 125′ (e.g., a pad in a metal layer-to-poly layer MP within a gate 121F-G of the device 121F). The second pad 125′ connects the second contact 124′ to the third pad 126′ (e.g., a pad in a second metal layer-to-poly layer MP2). The third pad 126′ connects the second pad 125′ to the second contact 127′ (e.g., a via). The second contact 127′ connects the second pad 125′ to the second signal line 131 of the third layer 13. The first pad 123′ connects to a source/drain terminal of a device 121F of the second layer 12. In these embodiments, the signal may be transmitted from the signal line 112 of the first layer 11 to the second signal line 131 of the second layer 12 through the gate 121F-G of the device 121F.

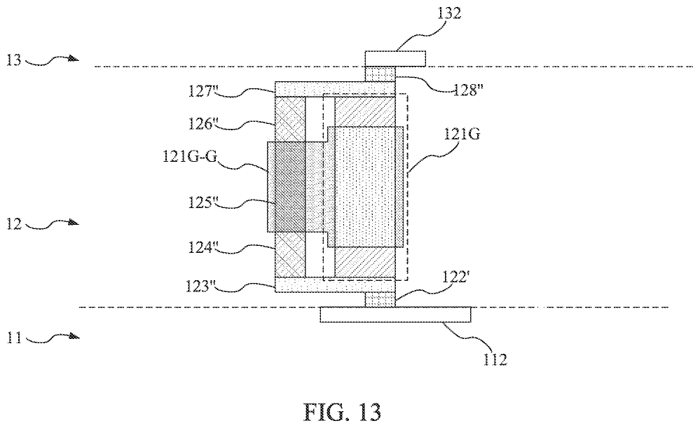

FIG. 13 is a schematic view of a part of the semiconductor structure 1 in accordance with some embodiments of the present disclosure. The second layer 12 includes a first contact 122″, a first pad 123″, a first isolation pad 124″, a second pad 125″, a second isolation pad 126″, a third pad 127″ and a second contact 128″, which are connected vertically with respect to the layers.

The first contact 122″ (e.g., a via) connects a signal line 112 (e.g., a metal line in metal zero layer MO) of the first layer 11 to the first pad 123″ (e.g., a bottom pad). The first isolation pad 124″ is disposed between the first pad 123″ and the second pad 125″ (e.g., a pad in a metal layer-to-poly layer MP within a gate 121G-G of the device 121G). The second isolation pad 126″ is disposed between the second pad 125″ and the third pad 127″ (e.g., a top pad). The second contact 128″ connects the third pad 127″ to the second signal line 131 of the third layer 13. The first pad 123″ connects to a source/drain terminal of a device 121G of the second layer 12. The third pad 127″ connects to a source/drain terminal of the device 121G. In these embodiments, the signal may not be transmitted from the signal line 112 of the first layer 11 to the second signal line 131 of the second layer 12 through a gate 121G-G of the device 121G.

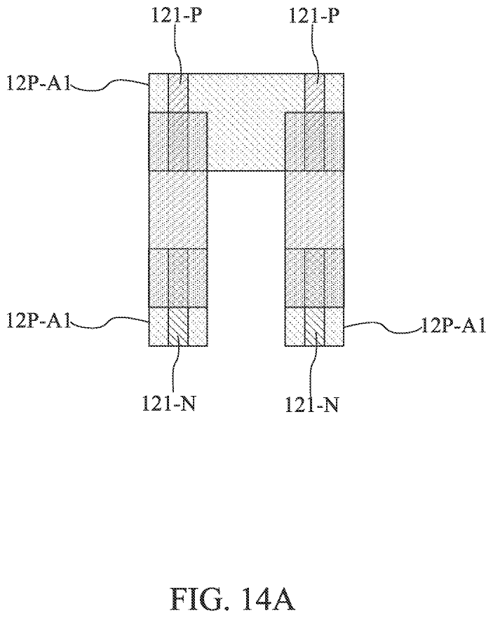

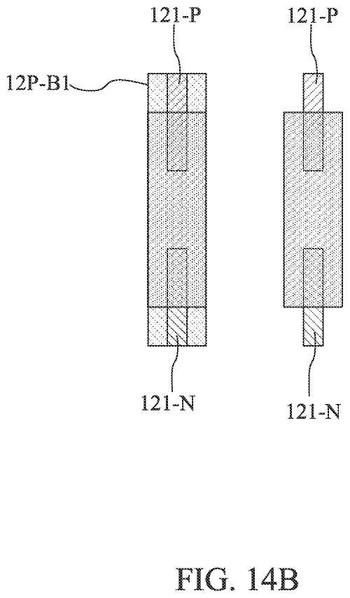

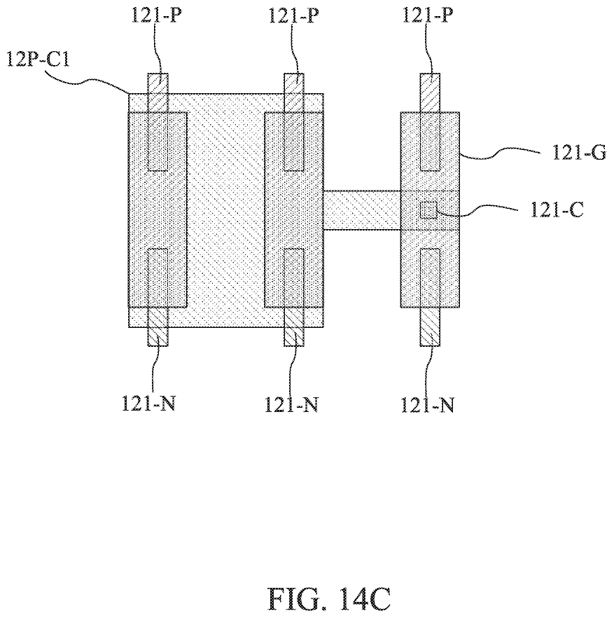

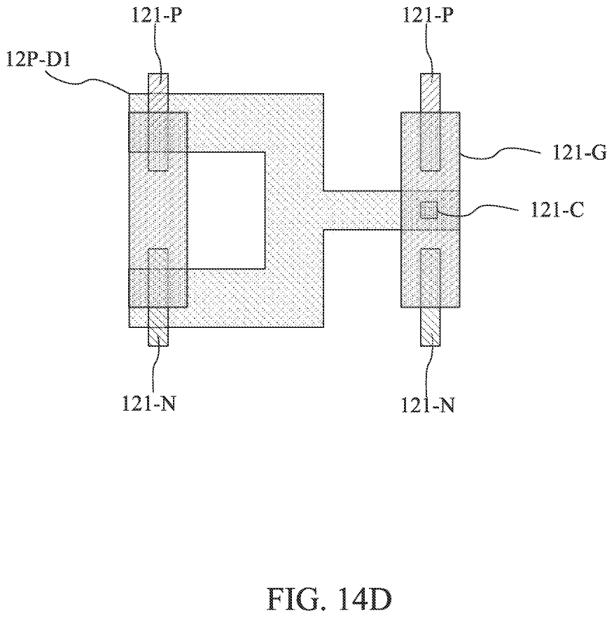

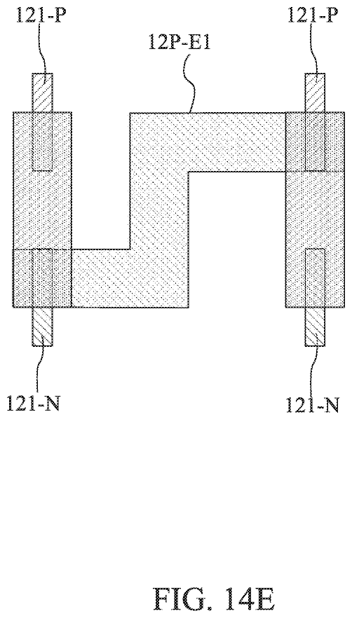

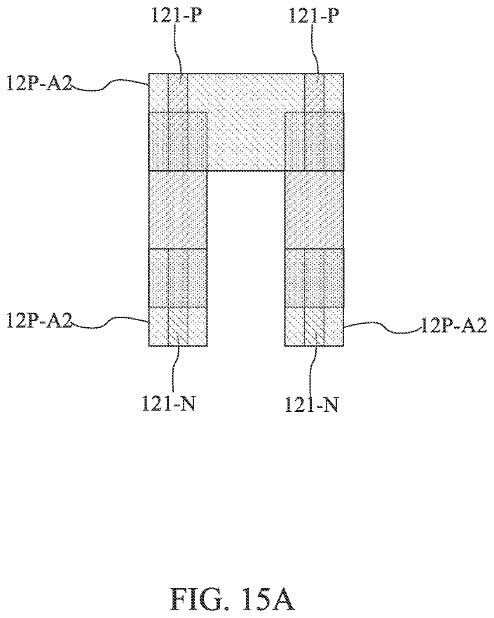

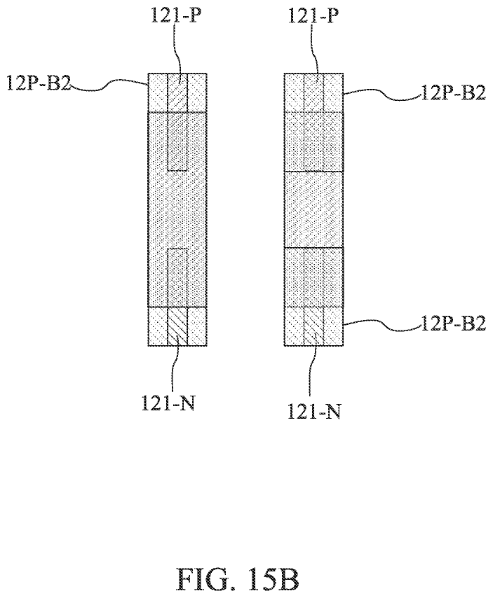

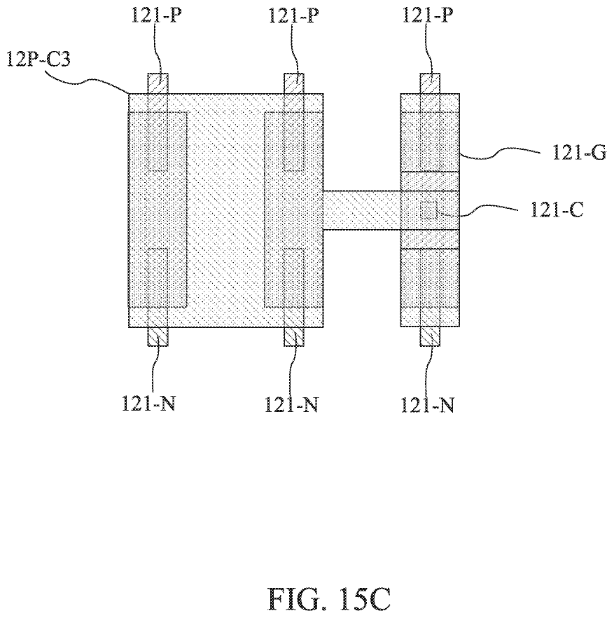

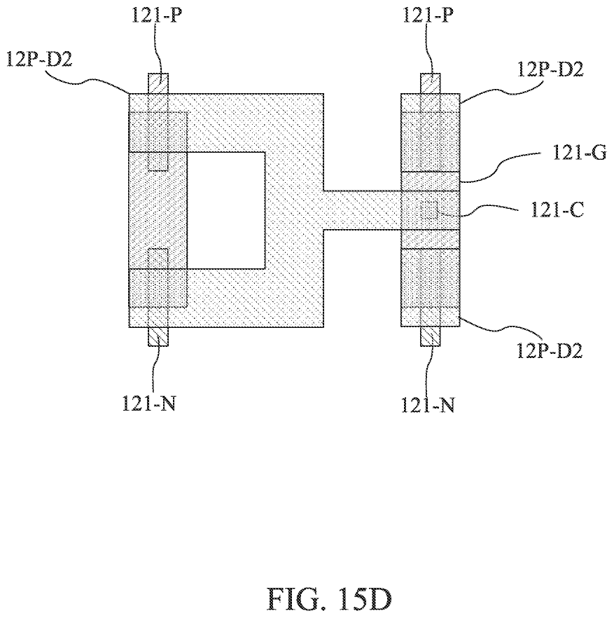

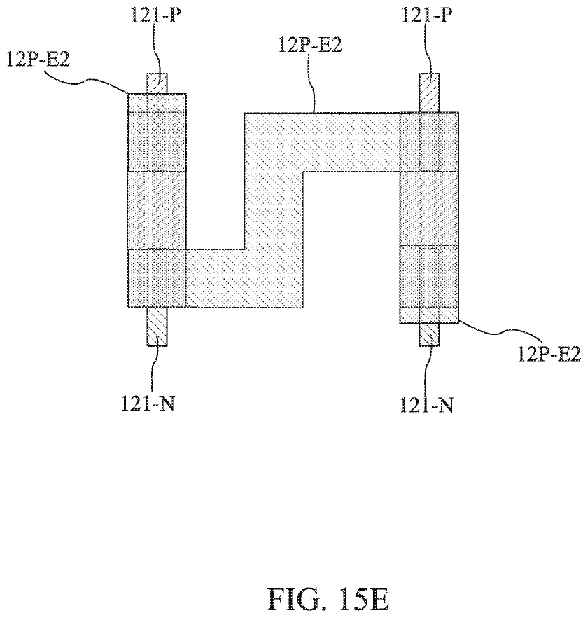

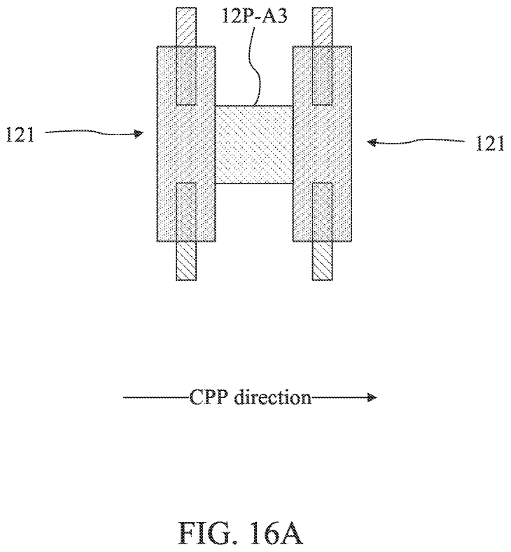

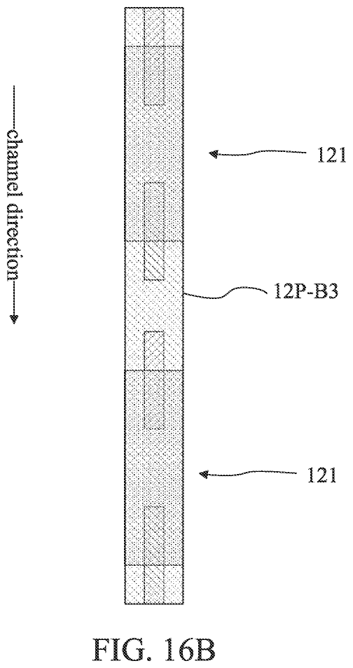

In some embodiments, to connect the VFET(s) in different ways within the second layer 12, there may be different shapes of pads. FIGS. 14A to 14E are schematic views of shapes of bottom pads (i.e., pad adjacent to the first layer 11) within the second layer 12 of a part of the semiconductor structure 1 in accordance with some embodiments of the present disclosure. FIGS. 15A to 15E are schematic views of shapes of top pads (i.e., pad adjacent to the third layer 13) within the second layer 12 of a part of the semiconductor structure 1 in accordance with some embodiments of the present disclosure. FIGS. 16A and 16B are schematic views of shapes of middle pads (i.e., gate pads) within the second layer 12 of a part of the semiconductor structure 1 in accordance with some embodiments of the present disclosure.

In FIG. 14A, there may be bottom pads 12P-A1. One of the pads 12P-A1 with strip shape connects two P-type VFETs 121-P. Each of the other pads 12P-A1 connects one N-type VFET 121-N. In some embodiments, the pads 12P-A1 with strip shape connects n number of P-type VFET(s) 121-P.

In FIG. 14B, there may be a bottom pad 12P-B1. The pad 12P-B1 with strip shape connects a pair of P-type VFET 121-P and an N-type VFET 121-N which form n channel. In some embodiments, the pad 12P-B1 with strip shape connects n number of pair(s) of P-type VFET(s) 121-P and n number of N-type VFET(s) 121-N which form n channel.

In FIG. 14C, there may be a bottom pad 12P-C1. The pad 12P-C1 with a ‘T’ shape connects two pairs of P-type VFETs 121-P and N-type VFETs 121, and a gate 121-G of one pair of P-type VFET 121-P and N-type VFET 121-N. In some embodiments, the pad 12P-C1 connects the gate 121-G of the pair of P-type VFET 121-P and N-type VFET 121-N via a contact (e.g., a deep via) 121-C. In some embodiments, the pad 12P-C1 with the ‘T’ shape connects n number of pair(s) of P-type VFET(s) 121-P and N-type VFET(s) 121, and m number of gate(s) 121-G of m number of pair(s) of P-type VFET(s) 121-P and N-type VFET(s) 121-N.

In FIG. 14D, there may be a bottom pad 12P-D1. The pad 12P-D1 with a ‘Y’ shape connects one pair of P-type VFET 121-P and N-type VFET 121-N and a gate 121-G of one pair of P-type VFET 121-P and N-type VFET 121-N. In some embodiments, the pad 12P-C1 connects the gate 121-G of the pair of P-type VFET 121-P and N-type VFET 121-N via a contact (e.g., a deep via) 121-C. In some embodiments, the pad 12P-D1 with the ‘Y’ shape connects one pair of P-type VFET 121-P and N-type VFET 121-N and n number of gate(s) 121-G of n number of pair(s) of P-type VFET 121-P(s) and N-type VFET(s) 121-N.

In FIG. 14E, there may be a bottom pad 12P-E1. The pad 12P-E1 with a ‘lighting’ shape connects a P-type VFET 121-P to an N-type VFET 121-N.

In FIG. 15A, there may be top pads 12P-A2. One of the pads 12P-A2 with strip shape connects two P-type VFETs 121-P. Each of the other pads 12P-A2 connects one N-type VFET 121-N. In some embodiments, the pads 12P-A2 with strip shape connects n number of P-type VFET(s) 121-P.

In FIG. 15B, there may be top pads 12P-B2. One of the pads 12P-B2 with strip shape connects a pair of P-type VFET 121-P and an N-type VFET 121-N which form n channel. One of the other two pads 12P-B2 connects another P-type VFET 121-P, and one of the other two pads 12P-B2 connects another N-type VFET 121-N. In some embodiments, the pad 12P-B2 with strip shape connects n number of P-type VFET(s) 121-P and n number of N-type VFET(s) 121-N which form n channel.

In FIG. 15C, there may be top pads 12P-C2. One of the pads 12P-C with a ‘T’ shape connects two pairs of P-type VFET 121-P and N-type VFET 121-N, and a gate 121-G of a pair of P-type VFET 121-P and N-type VFET 121-N. One of the other two pads 12P-C2 connects an N-type VFET of a pairs of P-type VFET 121-P and N-type VFET 121-N, and one of the other two pads 12P-C2 connects a P-type VFET of the pairs of P-type VFET 121-P and N-type VFET 121-N.

In FIG. 15D, there may be top pads 12P-D2. One of the pads 12P-D with a ‘Y’ shape connects one pair of P-type VFET 121-P and N-type VFET 121-N and a gate 121-G of a pair of P-type VFET 121-P and N-type VFET 121-N. One of the other two pads 12P-D2 connects an N-type VFET of a pair of P-type VFET 121-P and N-type VFET 121-N, and one of the other two pads 12P-D2 connects a P-type VFET of the pair of P-type VFET 121-P and N-type VFET 121-N.

In FIG. 15E, there may be top pads 12P-E2. One of the pads 12P-E2 with a ‘lighting’ shape connects a P-type VFET 121-P of a first device to an N-type VFET 121-N of a second device. Ones of the pad 12P-E2 connects an N-type VFET 121-N of the first device. One of the pads 12P-E2 connects a P-type VFET 121-P of the second device.

In FIG. 16A, there may be a gate pad 12P-A3. The gate pad 12P-A3 connects two gates of two devices 121 along CPP direction. In FIG. 16B, there may be a gate pad 12P-B3. The gate pad 12P-B3 connects gates of devices 121 along channel direction.

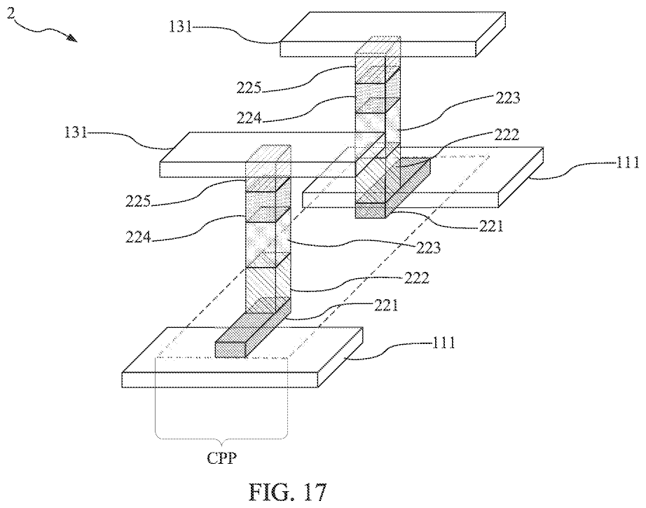

FIG. 17 is a schematic view of a power tap cell 2 of a part of the semiconductor structure 1 in accordance with some embodiments of the present disclosure. In some embodiments, the power tap cell 2 includes a pair of the first power lines 111, a pair of first pads 221 (e.g., bottom pads), a pair of first contacts 222 (e.g., deep vias), a pair of second pads 223 (e.g., pads in a metal layer-to-poly layer MP), a pair of third pads 224 (e.g., pads in a second metal layer-to-poly layer MP2), a pair of second contacts 225 (e.g., vias VD) and a pair of the second power lines 131. The power tap cell 2 may be deployed within one or more CPPs.

In some embodiments, the first pads 221 connects the first power lines 111 to the first contacts 222. The first contacts 222 connects the first pads 221 to the second pads 223. The second pads 223 connects the first contacts 222 to the third pads 224. The third pads 224 connects the second pads 223 to the second contacts 225. The second contacts 225 connects the third pads 224 to the second power lines 131.

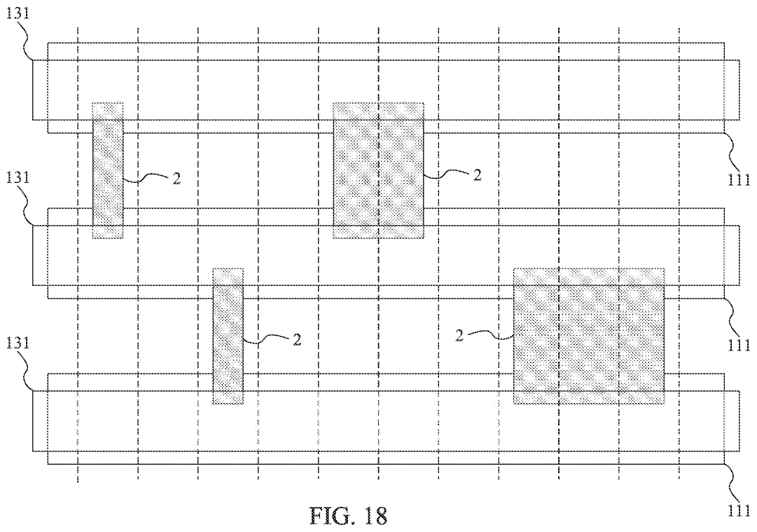

FIG. 18 is a schematic view of a placement of the power tap cells 2 of a part of the semiconductor structure 1 in accordance with some embodiments of the present disclosure. In some embodiments, some of the power tap cells 2 may be deployed within one CPP, and some of the power tap cells 2 may be deployed within two or three CPPs.

According to some embodiments, a semiconductor structure is provided. The semiconductor structure includes: a first layer including a plurality of first power lines; a second layer including a plurality of VFETs; a third layer including a plurality of second power line; wherein the second layer is disposed between the first layer and the third layer, a first part of the VETs is connected to the first power lines and a second part of the VETs is connected to the second power lines.

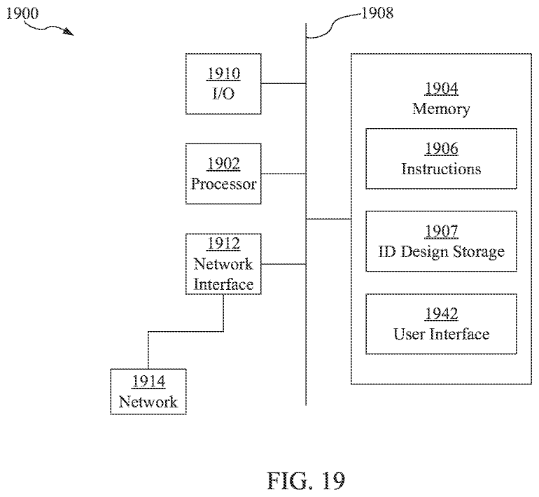

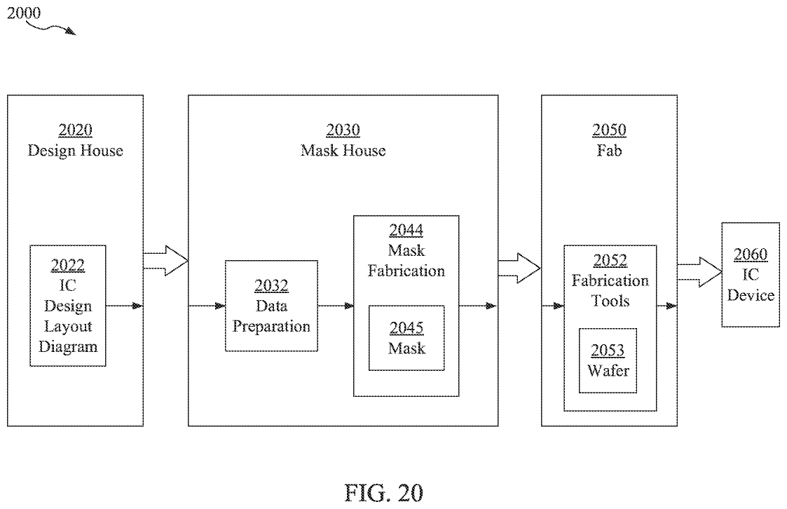

In some embodiments, the IC layout diagram is usable in a method executed using an IC layout diagram generation system 1000 discussed below with respect to FIG. 19 and/or an IC manufacturing flow associated with IC manufacturing system 2000 discussed below with respect to FIG. 20, as part of defining one or more features of the corresponding IC device. In some embodiments, an IC layout diagram is stored in an IC design storage medium such as an IC design storage 1907 discussed below with respect to FIG. 19.

FIG. 19 is a block diagram of IC design system 1900, in accordance with some embodiments. Methods described herein of designing IC layout diagrams in accordance with one or more embodiments are implementable, for example, using IC design system 1900, in accordance with some embodiments. In some embodiments, IC design system 1900 is an automatic placement and routing (APR) system, includes an APR system, or is part of an APR system, usable for performing an APR method.

In some embodiments, IC design system 1900 is a general purpose computing device including a hardware processor 1902 and non-transitory, computer-readable storage medium 1904. Storage medium 1904, amongst other things, is encoded with, i.e., stores, computer program code 1906, i.e., a set of executable instructions. Execution of instructions 1906 by hardware processor 1902 represents (at least in part) an EDA tool which implements a portion or all of a method, e.g., a method of generating an IC layout diagram described above (hereinafter, the noted processes and/or methods).

Processor 1902 is electrically coupled to computer-readable storage medium 1904 via a bus 1908. Processor 1902 is also electrically coupled to an I/O interface 1910 by bus 1908. Network interface 1912 is also electrically connected to processor 1902 via bus 1908. Network interface 1912 is connected to a network 1914, so that processor 1902 and computer-readable storage medium 1904 are capable of connecting to external elements via network 1914. Processor 1902 is configured to execute computer program code 1906 encoded in computer-readable storage medium 1904 in order to cause IC design system 1900 to be usable for performing a portion or all of the noted processes and/or methods. In some embodiments, processor 1902 is a central processing unit (CPU), a multi-processor, a distributed processing system, an application specific integrated circuit (ASIC), and/or a suitable processing unit.

In some embodiments, computer-readable storage medium 1904 is an electronic, magnetic, optical, electromagnetic, infrared, and/or a semiconductor system (or apparatus or device). For example, computer-readable storage medium 1904 includes a semiconductor or solid-state memory, a magnetic tape, a removable computer diskette, a random access memory (RAM), a read-only memory (ROM), a rigid magnetic disk, and/or an optical disk. In some embodiments using optical disks, computer-readable storage medium 1904 includes a compact disk-read only memory (CD-ROM), a compact disk-read/write (CD-R/W), and/or a digital video disc (DVD).

In some embodiments, storage medium 1904 stores computer program code 1906 configured to cause IC design system 1900 (where such execution represents (at least in part) the EDA tool) to be usable for performing a portion or all of the noted processes and/or methods. In some embodiments, storage medium 1904 also stores information which facilitates performing a portion or all of the noted processes and/or methods. In some embodiments, storage medium 1904 includes IC design storage 1907 configured to store one or more IC layout diagrams, e.g., an IC layout diagram discussed above with respect to FIGS. 1-4 and 7-18.

IC design system 1900 includes I/O interface 1910. I/O interface 1910 is coupled to external circuitry. In some embodiments, I/O interface 1910 includes a keyboard, keypad, mouse, trackball, trackpad, touchscreen, and/or cursor direction keys for communicating information and commands to processor 1902.

IC design system 1900 also includes network interface 1912 coupled to processor 1902. Network interface 1912 allows IC design system 1900 to communicate with network 1914, to which one or more other computer systems are connected. Network interface 1912 includes wireless network interfaces such as BLUETOOTH, WIFI, WIMAX, GPRS, or WCDMA; or wired network interfaces such as ETHERNET, USB, or IEEE-1364. In some embodiments, a portion or all of noted processes and/or methods, is implemented in two or more IC design systems 1900.

IC design system 1900 is configured to receive information through I/O interface 1910. The information received through I/O interface 1910 includes one or more of instructions, data, design rules, libraries of standard cells, and/or other parameters for processing by processor 1902. The information is transferred to processor 1902 via bus 1908. IC design system 1900 is configured to receive information related to a UI through I/O interface 1910. The information is stored in computer-readable medium 1004 as UI 1942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an electronic design automation (EDA) tool. In some embodiments, a portion or all of the noted processes and/or methods is implemented as a software application that is used by IC design system 1900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 20 is a block diagram of IC manufacturing system 2000, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 2000.

In FIG. 20, IC manufacturing system 2000 includes entities, such as a design house 2020, a mask house 2030, and an IC manufacturer/fabricator (“fab”) 2050, that interact with one another in the design, development, and manufacturing cycles and/or services related to manufacturing an IC device 2060. The entities in system 2000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 2020, mask house 2030, and IC fab 2050 is owned by a single larger company. In some embodiments, two or more of design house 2020, mask house 2030, and IC fab 2050 coexist in a common facility and use common resources.

Design house (or design team) 2020 generates an IC design layout diagram 2022. IC design layout diagram 2022 includes various geometrical patterns, e.g., an IC layout diagram discussed above. The geometrical patterns correspond to patterns of metal, oxide, or semiconductor layers that make up the various components of IC device 2060 to be fabricated. The various layers combine to form various IC features. For example, a portion of IC design layout diagram 2022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 2020 implements a proper design procedure to form IC design layout diagram 2022. The design procedure includes one or more of logic design, physical design or place and route. IC design layout diagram 2022 is presented in one or more data files having information of the geometrical patterns. For example, IC design layout diagram 2022 can be expressed in a GDSII file format or DFII file format.

Mask house 2030 includes data preparation 2032 and mask fabrication 2044. Mask house 2030 uses IC design layout diagram 2022 to manufacture one or more masks 2045 to be used for fabricating the various layers of IC device 2060 according to IC design layout diagram 2022. Mask house 2030 performs mask data preparation 2032, where IC design layout diagram 2022 is translated into a representative data file (RDF). Mask data preparation 2032 provides the RDF to mask fabrication 2044. Mask fabrication 2044 includes a mask writer. A mask writer converts the RDF to an image on a substrate, such as mask (reticle) 2045 or a semiconductor wafer 2053. The design layout diagram 2022 is manipulated by mask data preparation 2032 to comply with particular characteristics of the mask writer and/or requirements of IC fab 2050. In FIG. 20, mask data preparation 2032 and mask fabrication 2044 are illustrated as separate elements. In some embodiments, mask data preparation 2032 and mask fabrication 2044 can be collectively referred to as mask data preparation.

In some embodiments, mask data preparation 2032 includes optical proximity correction (OPC) which uses lithography enhancement techniques to compensate for image errors, such as those that can arise from diffraction, interference, other process effects and the like. OPC adjusts IC design layout diagram 2022. In some embodiments, mask data preparation 2032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 2032 includes a mask rule checker (MRC) that checks the IC design layout diagram 2022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 2022 to compensate for limitations during mask fabrication 2044, which may undo part of the modifications performed by OPC in order to meet mask creation rules.

In some embodiments, mask data preparation 2032 includes lithography process checking (LPC) that simulates processing that will be implemented by IC fab 2050 to fabricate IC device 2060. LPC simulates this processing based on IC design layout diagram 2022 to create a simulated manufactured device, such as IC device 2060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 2022.

It should be understood that the above description of mask data preparation 2032 has been simplified for the purposes of clarity. In some embodiments, data preparation 2032 includes additional features such as a logic operation (LOP) to modify the IC design layout diagram 2022 according to manufacturing rules. Additionally, the processes applied to IC design layout diagram 2022 during data preparation 2032 may be executed in a variety of different orders.

After mask data preparation 2032 and during mask fabrication 2044, a mask 2045 or a group of masks 2045 are fabricated based on the modified IC design layout diagram 2022. In some embodiments, mask fabrication 2044 includes performing one or more lithographic exposures based on IC design layout diagram 2022. In some embodiments, an electron-beam (e-beam) or a mechanism of multiple e-beams is used to form a pattern on a mask (photomask or reticle) 2045 based on the modified IC design layout diagram 2022. Mask 2045 can be formed in various technologies. In some embodiments, mask 2045 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 2045 includes a transparent substrate (e.g., fused quartz) and an opaque material (e.g., chromium) coated in the opaque regions of the binary mask. In another example, mask 2045 is formed using a phase shift technology. In a phase shift mask (PSM) version of mask 2045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 2044 is used in a variety of processes. For example, such a mask(s) is used in an ion implantation process to form various doped regions in semiconductor wafer 2053, in an etching process to form various etching regions in semiconductor wafer 2053, and/or in other suitable processes.

IC fab 2050 is an IC fabrication business that includes one or more manufacturing facilities for the fabrication of a variety of different IC products. In some embodiments, IC Fab 2050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 2050 includes wafer fabrication tools 2052 configured to execute various manufacturing operations on semiconductor wafer 2053 such that IC device 2060 is fabricated in accordance with the mask(s), e.g., mask 2045. In various embodiments, fabrication tools 2052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 2050 uses mask(s) 2045 fabricated by mask house 2030 to fabricate IC device 2060. Thus, IC fab 2050 at least indirectly uses IC design layout diagram 2022 to fabricate IC device 2060. In some embodiments, semiconductor wafer 2053 is fabricated by IC fab 2050 using mask(s) 2045 to form IC device 2060. In some embodiments, the IC fabrication includes performing one or more lithographic exposures based at least indirectly on IC design layout diagram 2022. Semiconductor wafer 2053 includes a silicon substrate or other proper substrate having material layers formed thereon. Semiconductor wafer 2053 further includes one or more of various doped regions, dielectric features, multilevel interconnects, and the like (formed at subsequent manufacturing steps).

Details regarding an IC manufacturing system (e.g., system 2000 of FIG. 20), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

According to other embodiments, a semiconductor structure is provided. The semiconductor structure includes: a plurality of first signal lines within a first layer, wherein the first signal lines include two first power lines; a plurality of VFETs within a second layer; a plurality of second signal lines within a third layer, wherein the second signal lines include two second power lines; wherein the second layer is disposed between the first layer and the third layer, a first part of the VETs is connected to the first power lines and a second part of the VETs is connected to the second power lines.

According to other embodiments, a semiconductor structure is provided. The semiconductor structure includes: a plurality of first power lines; a plurality of second power lines; and a plurality of vertical field effect transistors (VFETs) disposed between the first power lines and the second power lines; wherein a first VFET of the VFETs connects to one of the first power lines or one of the second power lines.

The structures and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor structure, comprising:
a first layer including a plurality of first power lines;
a second layer including a plurality of vertical field effect transistors (VFETs);
a third layer including a plurality of second power line;
wherein the second layer is disposed between the first layer and the third layer, a first part of the VETs is connected to the first power lines and a second part of the VETs is connected to the second power lines.

2. The semiconductor structure of claim 1, wherein the first power lines and the second power lines extend along a first direction.

3. The semiconductor structure of claim 2, wherein the third layer includes a plurality of first signal lines extend along the first direction.

4. The semiconductor structure of claim 2, further comprising:
a fourth layer including a plurality of second signal lines.

5. The semiconductor structure of claim 4, wherein the second signal lines extend along a second direction and the first direction is perpendicular to the second direction.

6. The semiconductor structure of claim 5, wherein within one contacted poly pitch associated with the semiconductor structure, a ratio of a number of the second signal lines to the one contacted poly pitch is greater than 1.5.

7. The semiconductor structure of claim 1, wherein a first VFET of the VFETs has a drain and a source, and a plurality of channels are between the drain and the source.

8. The semiconductor structure of claim 1, wherein the second layer further includes a first contact, a first pad, a second contact, a second pad, a third pad, a fourth pad and a second contact which are connected, the first contact connects to a first signal line of the first layer and the second contact connects to a second signal line of the third layer.

9. The semiconductor structure of claim 1, wherein the second layer further includes a first contact, a first pad, a second contact, a second pad, a third pad and a second contact which are connected, the first contact connects to a first signal line of the first layer and the second contact connects to a second signal line of the third layer.

10. The semiconductor structure of claim 1, wherein the second layer further includes a pad, and the pad connects a first pair of VFETs to a second pair of VFETs.

11. A semiconductor structure, comprising:
a plurality of first conductive lines within a first layer, wherein the first conductive lines include two first power lines;
a plurality of vertical field effect transistors (VFETs) within a second layer;
a plurality of second conductive lines within a third layer, wherein the second conductive lines include two second power lines;
wherein the second layer is disposed between the first layer and the third layer, a first part of the VETs is connected to the first power lines and a second part of the VETs is connected to the second power lines.

12. The semiconductor structure of claim 11, wherein the first conductive lines and the second conductive lines extend along a first direction.

13. The semiconductor structure of claim 12, further comprising:
a plurality of third conductive lines within a fourth layer.

14. The semiconductor structure of claim 13, wherein the third conductive lines extend along a second direction and the first direction is perpendicular to the second direction.

15. The semiconductor structure of claim 14, wherein within one contacted poly pitch associated with the semiconductor structure, a ratio of a number of the second conductive lines to the one contacted poly pitch is greater than 2.

16. The semiconductor structure of claim 11, wherein a first VFET of the VFETs has a drain and a source, and a plurality of channels are formed between the drain and the source.

17. The semiconductor structure of claim 11, wherein the second layer further includes a first contact, a first pad, a second contact, a second pad, a third pad and a second contact which are connected, the first contact connects to one of the first conductive lines and the second contact connects to one of the second conductive lines.

18. A semiconductor structure, comprising:
a plurality of first power lines;
a plurality of second power lines; and
a plurality of vertical field effect transistors (VFETs) disposed between the first power lines and the second power lines;
wherein a first VFET of the VFETs connects to one of the first power lines or one of the second power lines.

19. The semiconductor structure of claim 18, wherein the first power lines and the second power lines extend along the same direction.

20. The semiconductor structure of claim 19, further comprising:
a power tap cell, including the first power lines, the second power lines, a pair of first pads, a pair of first contacts, a pair of second pads, a pair of third pads and a pair of second contacts.
